(19) United States
(12) Patent Application Publication
(10) Pub. No.: US 2009/0289376 A1
(43) Pub. Date: Nov. 26, 2009

(54) LIGHT-PROOF CHIP PACKAGING STRUCTURE AND METHOD FOR ITS MANUFACTURE

(75) Inventors: Ming-Chih CHIEN, Taoyuan County (TW); Jung-Hsiu Chen, Taoyuan County (TW)

Correspondence Address: Muncy, Geissler, Olds & Lowe, PLLC, P.O. BOX 1364, FAIRFAX, VA, 22038-1364, US

(73) Assignee: SIPIX TECHNOLOGY INC.

(21) Appl. No.: 12/125,365

(22) Filed: May 22, 2008

(51) Int. Cl. H01L 23/29; H01L 21/56

(52) U.S. Cl. 257/792; 438/118; 257/E21.502; 257/E23.119

(57) ABSTRACT

The present invention discloses a light-proof chip packaging structure, which comprises an electronic substrate, at least one semiconductor chip installed on the electronic substrate, and a light-proof film. The light-proof film comprises a main portion, which is substantially conformable to cover all the non-concealed faces of the semiconductor chip. The light-proof film also has an extension portion, which extends from the main portion and covers the areas neighboring the semiconductor chip. The light-proof film comprises a metallic layer capable of blocking light and an insulating layer interposing between the metallic layer and the semiconductor chip. The present invention can effectively reduce the gaps between the semiconductor chip and the light-proof film, whereby no bubble is formed in encapsulating the electronic substrate, thus reducing the possibility of damaging the packing structure.

### FIELD OF THE INVENTION

The present invention relates to a chip packaging structure, particularly to a light-proof chip packaging structure, which can protect a semiconductor chip from light radiation.

### BACKGROUND OF THE INVENTION

The Smart Card is a plastic card wherein an IC chip is embedded; therefore, it is also called the IC Card or ICC (Integrated Circuit Card). As an integrated circuit chip (hereinafter called IC chip for short) has the functions of storing, encrypting and processing data, it has been used in many fields, such as finance, communication, trading, verification, personal identification, etc. More specifically, it can be used for credit cards, electronic wallets, and personal identity cards. US patents of U.S. Pat. No. 7,341,198, U.S. Pat. No. 7,337,978, and U.S. Pat. No. 7,293,717 disclose the above-mentioned integrated circuit chip in the related technologies. In addition to an IC chip, the Smart Card also has a high capacity slim battery driving circuits on the electronic substrate.

However, heat may cause current leakage, lower the performance of circuits, or even damage the IC chip. Limited by its dimensions, the Smart Card has no heat-dissipation component. Smart cards are normally carried about by users and likely to be exposed to external environments. Direct light or scattered light may pass through the surface of the Smart Card and reach the IC chip and then is converted into heat to raise the temperature of the IC chip, which will degrade the stability of the IC chip, lower the endurance of the battery, and thus shorten the lifetime of the Smart Card.

FIG. 1 shows a conventional technology. Prior to the present invention, a plastic material is used to encapsulate the IC chip 1, a light-proof tape 2 is adhered on an IC chip 1 lest the radiation heat of light illumination may raise the temperature of the IC chip 1. The light-proof tape 2 is a flexible material, and the IC chip 1 protrudes from an electronic substrate 3. When the light-proof tape 2 is adhered to the IC chip 1, it cannot closely contact the areas neighboring the edges of the IC chip 1, thus leaving gaps 4 in those areas. In FIG. 2, when the Smart Card 6 is packaged, the light-proof tape 2 is heat-pressed onto the surface of the IC chip 1, but the air in the gaps 4 is squeezed out causing bubbles 5 to form inside the Smart Card 6. The bubbles 5 results in an imperfect package of the Smart Card 6 and damages the structural integrity of the Smart Card 6, which makes the Smart Card 6 easy to break consequently affecting its operation.

### SUMMARY OF THE INVENTION

The primary objective of the present invention is to solve the problem of gaps between an IC chip and a light-proof material for packaging a Smart Card. The gap often causes the formation of bubbles, which damages the packaging structure of the Smart Card.

To achieve the abovementioned objective, the present invention proposes a light-proof chip packaging method, which comprises steps: (a) installing one or more semiconductor chip, wherein at least one semiconductor chip is installed on an electronic substrate; (b) covering the semiconductor chip and its neighboring areas with a light-proof film, wherein the light-proof film comprises a metallic layer and an insulating layer; and (c) applying pressure to the light-proof film to cause the light-proof film to be substantially conformable to cover all non-concealed faces of the semiconductor chip and the areas neighboring the semiconductor chip.

The method may further comprise adding an adhesive layer to the light-proof film to cause the light-proof film to be substantially conformable to adhere to all the non-concealed faces of the semiconductor chip by pressure.

The present invention also proposes a light-proof chip packaging structure, which comprises: an electronic substrate, at least one semiconductor chip installed on the electronic substrate, and a light-proof film. The light-proof film comprises a main portion, which is substantially conformable to the shape of the semiconductor chip, and covers all the non-concealed faces of the semiconductor chip. The light-proof film also has an extension portion, which extends from the main portion and covers the areas neighboring the semiconductor chip. The light-proof film comprises a metallic layer capable of blocking light and an insulating layer interposing between the metallic layer and the semiconductor chip. In one embodiment of the present invention, the light-proof film further comprises an adhesive layer interposing between the insulating layer and the semiconductor chip, whereby the light-proof film can be adheres to the semiconductor chip.

In the present invention, a light-proof film having plasticity is used to cover the semiconductor chip, and a slight pressure is applied to the light-proof film to make the light-proof film substantially conformable to all the non-concealed faces of the semiconductor chip. Thereby, the gaps between the light-proof film and the semiconductor chip are eliminated, and no bubble will form in the packaging process of the Smart Card. Thus, the Smart Card is perfectly encapsulated, and the circuits on the electronic substrate will operate normally.

### BRIEF DESCRIPTION OF THE DRAWINGS

FIG. 1 is a sectional view schematically showing that a flexible light-proof tape is attached to an IC chip in a conventional technology.

FIG. 2 is a sectional view schematically showing that bubbles are formed inside a flexible light-proof tape during an encapsulation process in a conventional technology.

FIG. 3 is a flowchart of a light-proof chip packaging method according to a preferred embodiment of the present invention.

FIG. 4 is a perspective view schematically showing a light-proof chip packaging structure according to a preferred embodiment of the present invention.

FIG. 5 is a sectional view schematically showing a light-proof chip packaging structure according to a preferred embodiment of the present invention.

FIG. 6 is a sectional view schematically showing an embodiment that the light-proof chip packaging structure of the present invention is applied to a Smart Card.

FIG. 7 is a perspective view schematically showing another embodiment that the light-proof chip packaging structure of the present invention is applied to a Smart Card.

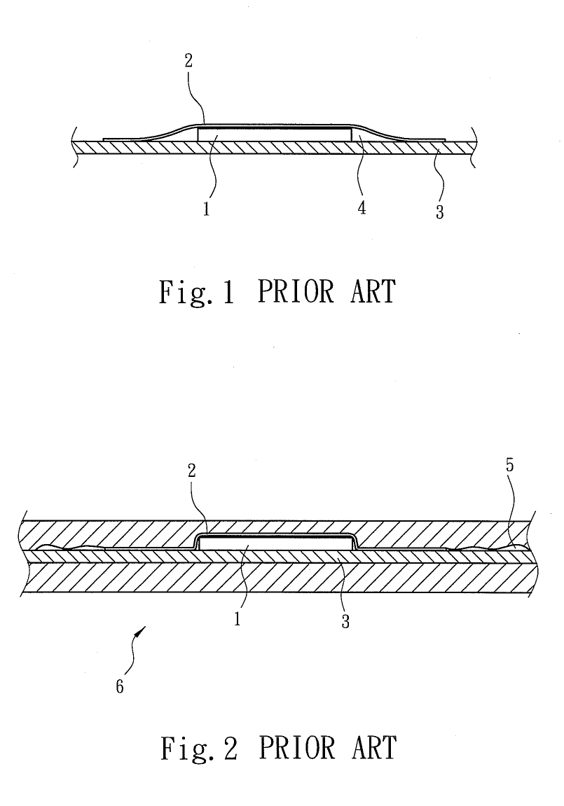

### DETAILED DESCRIPTION OF THE PREFERRED EMBODIMENTS

Below, the technical contents of the present invention will be described in detail in cooperation with the drawings.

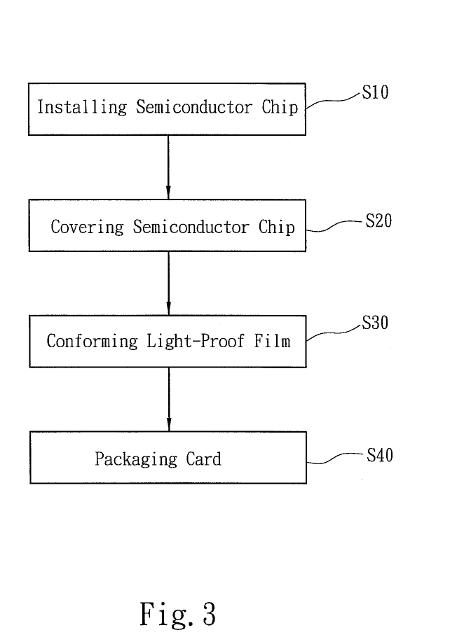

FIG. 3 shows a flowchart of a light-proof chip packaging method according to a preferred embodiment of the present invention. In this embodiment, the light-proof chip packaging method comprises steps:
(a) installing one or more semiconductor chip (Step S10), wherein at least one semiconductor chip is installed on an electronic substrate;
(b) covering the semiconductor chip and its neighboring areas (Step S20) with a light-proof film wherein the light-proof film comprises a metallic layer and an insulating layer; and
(c) applying pressure to the light-proof film (Step S30) to cause the light-proof film to be substantially conformable to cover all non-concealed faces of the semiconductor chip and the areas neighboring the semiconductor chip.

In this embodiment, the semiconductor chip and the electronic substrate are to be used in a Smart Card. Thus, after Step S30, there is a Step S40 for packaging the Smart Card, wherein the electronic substrate is encapsulated with a plastic material. Besides, the light-proof film further comprises an adhesive layer, whereby the light-proof film can be substantially conformable to adhere to all the non-concealed faces of the semiconductor chip by pressure in Step S30. Before Step S40, the present invention uses a light-proof film having plasticity to cover the semiconductor chip, and a pressure is applied to the light-proof film to make the light-proof film substantially conformable to cover all the non-concealed faces of the semiconductor chip and the areas neighboring the semiconductor chip. Thereby, the gaps between the light-proof film and the semiconductor chip are eliminated, and no bubble will form in Step S40.

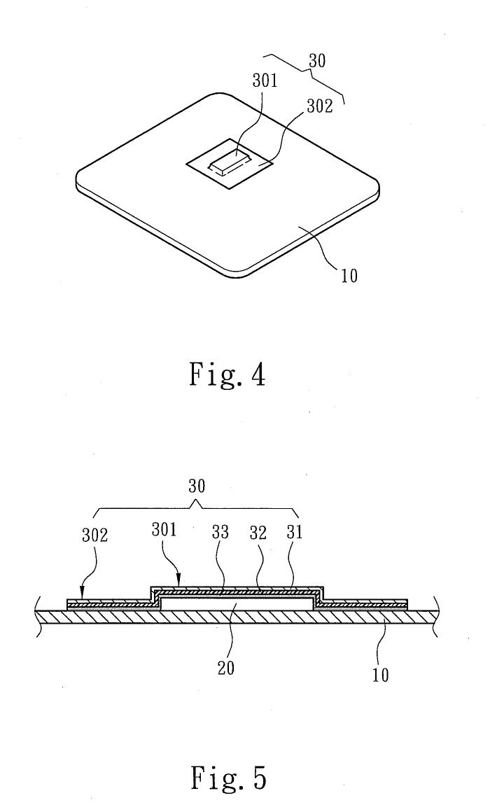

The present invention also proposes a light-proof chip packaging structure. FIG. 4 and FIG. 5 respectively show a perspective view and a sectional view of a light-proof chip packaging structure according to a preferred embodiment of the present invention. In this embodiment, the light-proof chip packaging structure comprises an electronic substrate 10, at least one semiconductor chip 20 installed on the electronic substrate 10, and a light-proof film 30. The light-proof film 30 comprises a main portion 301, which is substantially conformable to cover all the non-concealed faces of the semiconductor chip 20. The light-proof film 30 also comprises an extension portion 302, which extends from the main portion 301 and covers the areas neighboring the semiconductor chip 20. The light-proof film 30 comprises a metallic layer 31 capable of blocking light and an insulating layer 32 interposing between the metallic layer 31 and the semiconductor chip 20. The metallic layer 31 is a layer made of a flexible metallic material having plasticity and having an elongation of at least 6% at an ambient temperature. Suitable metallic layer may include, but is not limited to a copper layer or an aluminum layer. The insulating layer 32 is used to prevent the semiconductor chip 20 and electronic substrate 10 from contacting the metallic layer 31 lest a short circuit may occur. The insulating layer 32 is made of a flexible material capable of carrying the metallic layer 31. The insulating layer may include, but is not limited to PET (Poly(Ethylene Terephthalate)), PEN (Poly(Ethylene Naphthalate)), or PI (Polyimide). The metallic layer 31 is formed on the insulating layer 32 via a calendering method or an electroplating method. In this embodiment, the light-proof film 30 further comprises an adhesive layer 33 interposing between the insulating layer 32 and the semiconductor chip 20, whereby the light-proof film 30 can be securely adhered to the semiconductor chip 20. The adhesive layer 33 may be a pressure-sensitive adhesive tape or a thermosetting adhesive tape.

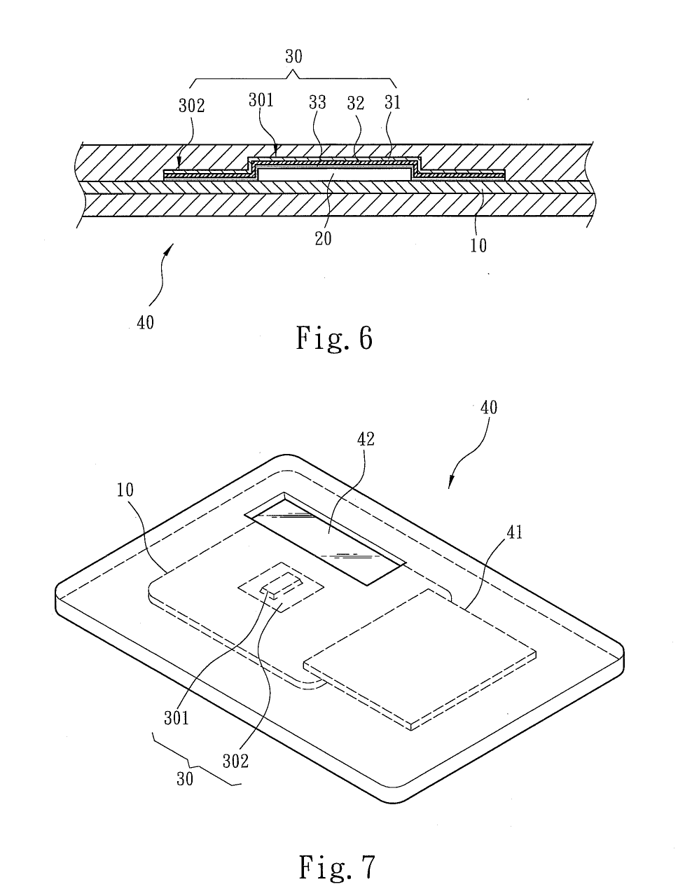

The light-proof chip packaging structure of the present invention is applicable to many electronic devices, such as Smart cards, RFID (Radio Frequency Identification) tags, or other slim electronic devices. FIG. 6 is a sectional view schematically showing an embodiment that the light-proof chip packaging structure of the present invention is applied to a Smart Card 40. Constrained by the thickness of the Smart Card 40, the thickness of the light-proof film 30 is less than or equal to 145 μm lest the surface of the Smart Card cannot be fully flattened. FIG. 7 is a perspective view schematically showing an embodiment that the light-proof chip packaging structure of the present invention is applied to a Smart Card 40. In this embodiment, a power unit 41 is connected with the electronic substrate 10 and used to drive the electronic substrate 10. The power unit 41 may be a lithium battery, a lithium ion battery, or a polymer electrolyte battery. Further, a display 42 may be connected with the electronic substrate 10 and used to present the data stored in electronic substrate 10 or the results of the operations of the electronic substrate 10. The display 42 may be a liquid crystal display or an electrophoresis display, whereby a user can view the information inside the Smart Card 40 without using a card reader.

In the present invention, a light-proof film 30 having plasticity is arranged on a semiconductor chip 20, and a pressure is applied to the light-proof film 30 to make the light-proof film 30 substantially conformable to cover all the non-concealed faces of the semiconductor chip 20 and the areas neighboring the semiconductor chip 20. Thereby, the gaps between the light-proof film 30 and the semiconductor chip 20 are eliminated, and no bubble will form in the packaging process of the Smart Card.

From the above description, the present invention represents improvements over the prior arts and meets the conditions for a patent.

The preferred embodiments described above are only to exemplify the present invention but not to limit the scope of the present invention. Therefore, any equivalent modification or variation according to the spirit of the present invention is to be also included within the scope of the present invention.

What is claimed is:

1. A light-proof chip packaging method, comprising steps:
installing one or more semiconductor chip, wherein at least one semiconductor chip is installed on an electronic substrate;
covering said semiconductor chip and its neighboring areas with a light-proof film, wherein said light-proof film comprises a metallic layer and an insulating layer; and
applying pressure to said light-proof film to make said light-proof film substantially conformable to cover all non-concealed faces of said semiconductor chip and its neighboring areas.

2. The light-proof chip packaging method according to claim 1, further comprising adding an adhesive layer to the light-proof film to cause the light-proof film to be substantially conformable to adhere to all the non-concealed faces of said semiconductor chip.

3. The light-proof chip packaging method according to claim 1 further comprising a packaging step of encapsulating said electronic substrate with a plastic material.

4. A light-proof chip packaging structure, comprising:
an electronic substrate comprising one or more semiconductor chip; and
a light-proof film, wherein said light-proof film comprises a main portion substantially conformable to cover all non-concealed faces of said semiconductor chip, and an extension portion extending from said main portion and covering areas neighboring said semiconductor chip, and wherein said light-proof film comprises a metallic layer, and an insulating layer interposing between said metallic layer and said semiconductor chip.

5. The light-proof chip packaging structure according to claim 4 further comprising an adhesive layer interposing between said insulating layer and said semiconductor chip.

6. The light-proof chip packaging structure according to claim 5, wherein said adhesive layer is a pressure-sensitive adhesive tape.

7. The light-proof chip packaging structure according to claim 5, wherein said adhesive layer is a thermosetting adhesive tape.

8. The light-proof chip packaging structure according to claim 4, wherein said light-proof film has a thickness less than or equal to 145 μm.

9. The light-proof chip packaging structure according to claim 4, wherein said metallic layer is a copper layer.

10. The light-proof chip packaging structure according to claim 4, wherein said metallic layer is an aluminum layer.

11. The light-proof chip packaging structure according to claim 4, wherein said metallic layer has an elongation of at least 6% at an ambient temperature.

12. The light-proof chip packaging structure according to claim 4, wherein said insulating layer is made of a material selected from the group consisting of PET (Poly(Ethylene Terephthalate)), PEN (Poly(Ethylene Naphthalate)), and PI (Polyimide).

13. The light-proof chip packaging structure according to claim 4, wherein said metallic layer is formed on said insulating layer via a calendering method or an electroplating method.

14. The light-proof chip packaging structure according to claim 4, wherein a power unit is electrically connected with said electronic substrate.

15. The light-proof chip packaging structure according to claim 4, wherein a display is electrically connected with said electronic substrate.
